(19) United States
(12) Patent Application Publication
(10) Pub. No.: US 2024/0373716 A1
(43) Pub. Date: Nov. 7, 2024

(54) DISPLAY PANEL AND DISPLAY DEVICE

(71) Applicant: Wuhan Tianma Micro-Electronics Co., Ltd., Wuhan (CN)

(72) Inventors: Xuyang FANG, Wuhan (CN); Wanqiu ZHANG, Wuhan (CN)

(21) Appl. No.: 18/404,298

(22) Filed: Jan. 4, 2024

(30) Foreign Application Priority Data
May 5, 2023 (CN) 202310521996.X

(51) Int. Cl. H10K 59/38; H10K 59/126; H10K 59/35

(52) U.S. Cl. CPC H10K 59/38; H10K 59/126; H10K 59/35

(57) ABSTRACT

Display panel and display device are provided. The display panel includes a substrate, a light-emitting layer on a side of the substrate, and a color filter layer on a side of the light-emitting layer away from the substrate. The light-emitting layer includes a plurality of pixel openings, the color filter layer includes a plurality of color resists, a light-shielding layer is filled between adjacent color resists. A color resist of the plurality of color resists includes a first surface and a second surface oppositely arranged, and a first side connecting the first surface and the second surface, the light-shielding layer covers the first side, and the first surface is between the second surface and the substrate. The display panel further includes a reflective layer between the light-shielding layer and the first side of the first color resist.

### CROSS-REFERENCE TO RELATED APPLICATION

This application claims priority of Chinese Patent Application No. 202310521996.X, filed on May 5, 2023, the entire contents of which are hereby incorporated by reference.

### FIELD OF THE DISCLOSURE

The present disclosure generally relates to the field of display technology and, more particularly, relates to a display panel and a display device.

### BACKGROUND

Display panels often include Organic Light Emitting Diode (OLED), Liquid Crystal Display (LCD), Plasma Display Panel (PDP) and the like. An organic light emitting display device, which is a self-luminous display device, does not require a separate light source. Therefore, the organic light emitting display device can operate at a low voltage, is lightweight and thin, and provides high-quality characteristics such as wide viewing angle, high contrast ratio, and quick response. An OLED can be used as a light source for display devices and lighting devices. An OLED exhibits low energy consumption, high resolution, fast response and other excellent optoelectronic properties, and has gradually become a mainstream display technology.

For OLED displays, how to improve a light extraction efficiency of a light-emitting layer has become one of technical problems to be solved urgently at present.

### BRIEF SUMMARY OF THE DISCLOSURE

One aspect of the present disclosure provides a display panel. The display panel includes a substrate, a light-emitting layer on a side of the substrate, and a color filter layer on a side of the light-emitting layer away from the substrate. The light-emitting layer includes a plurality of pixel openings, the color filter layer includes a plurality of color resists, a light-shielding layer is filled between adjacent color resists, and along a first direction, the plurality of color resists overlaps the plurality of pixel openings, and the first direction is perpendicular to a plane where the substrate is located. A color resist of the plurality of color resists includes a first surface and a second surface oppositely arranged along the first direction, and a first side connecting the first surface and the second surface, the light-shielding layer covers the first side, and the first surface is between the second surface and the substrate. The plurality of color resists includes a first color resist, in the first color resist, along the first direction, an orthographic projection of the first side facing the substrate overlaps an orthographic projection of the first surface facing the substrate. The display panel further includes a reflective layer between the light-shielding layer and the first side of the first color resist.

Another aspect of the present disclosure provides a display device including a display panel. The display panel includes a substrate, a light-emitting layer on a side of the substrate, and a color filter layer on a side of the light-emitting layer away from the substrate. The light-emitting layer includes a plurality of pixel openings, the color filter layer includes a plurality of color resists, a light-shielding layer is filled between adjacent color resists, and along a first direction, the plurality of color resists overlaps the plurality of pixel openings, and the first direction is perpendicular to a plane where the substrate is located. A color resist of the plurality of color resists includes a first surface and a second surface oppositely arranged along the first direction, and a first side connecting the first surface and the second surface, the light-shielding layer covers the first side, and the first surface is between the second surface and the substrate. The plurality of color resists includes a first color resist, in the first color resist, along the first direction, an orthographic projection of the first side facing the substrate overlaps an orthographic projection of the first surface facing the substrate. The display panel further includes a reflective layer between the light-shielding layer and the first side of the first color resist.

Other aspects of the present disclosure can be understood by a person skilled in the art in light of the description, the claims, and the drawings of the present disclosure.

### BRIEF DESCRIPTION OF THE DRAWINGS

Accompanying drawings, which are incorporated into and constitute a part of the present specification, illustrate embodiments of the present disclosure and together with the description, serve to explain principles of the present disclosure.

FIG. 1 illustrates a schematic diagram of a display panel consistent with various embodiments of the present disclosure;

FIG. 2 illustrates an AA cross-sectional view of the display panel in FIG. 1;

FIG. 3 illustrates another AA cross-sectional view of the display panel in FIG. 1;

FIG. 4 illustrates a BB cross-sectional view of the display panel in FIG. 1;

FIG. 5 illustrates another BB cross-sectional view of the display panel in FIG. 1;

FIG. 6 illustrates another BB cross-sectional view of the display panel in FIG. 1;

FIG. 7 illustrates another BB cross-sectional view of the display panel in FIG. 1;

FIG. 8 illustrates another BB cross-sectional view of the display panel in FIG. 1;

FIG. 9 illustrates a schematic diagram of an arrangement of sub-pixels in a display panel consistent with various embodiments of the present disclosure;

FIG. 10 illustrates a CC cross-sectional view of the display panel in FIG. 9;

FIG. 11 illustrates a top view relationship diagram of a pixel opening and a second surface of a color resist;

FIG. 12 illustrates a schematic diagram of a relative positional relationship between a first color resist and a pixel opening in a display panel consistent with various embodiments of the present disclosure;

FIG. 13 illustrates another schematic diagram of an arrangement of sub-pixels in a display panel consistent with various embodiments of the present disclosure;

FIG. 14 illustrates a DD cross-sectional view of the display panel in FIG. 13;

FIG. 15 illustrates a top view relationship diagram of a pixel opening and a second surface of a first color resist in a display panel;

FIG. 16 illustrates another top view relationship diagram of a pixel opening and a second surface of a first color resist in a display panel;

FIG. 17 illustrates another AA cross-sectional view of the display panel in FIG. 1; and

FIG. 18 illustrates a schematic diagram of a display device consistent with various embodiments of the present disclosure.

### DETAILED DESCRIPTION

Various exemplary embodiments of the present disclosure will be described in detail with reference to the accompanying drawings. It should be noted that, unless specifically stated otherwise, a relative arrangement of components and steps, numerical expressions and numerical values set forth in the embodiments do not limit the scope of the present disclosure.

The following description of at least one exemplary embodiment is merely illustrative and is not intended to limit the present disclosure and application or use thereof.

Techniques, methods, and apparatus known to a person skilled in the art may not be discussed in detail, but where appropriate, such techniques, methods, and apparatus should be considered as part of the present specification.

In all examples shown and discussed herein, any specific value should be construed as illustrative only and not as a limitation. Accordingly, other examples of exemplary embodiments may have different values.

It will be apparent to a person skilled in the art that various modifications and variations can be made in the present disclosure without departing from the spirit or scope of the present disclosure. Accordingly, the present disclosure is intended to cover the modifications and variations of the present disclosure that fall within the scope of corresponding claims (claimed technical solutions) and equivalents thereof. It should be noted that, implementations provided in the embodiments of the present disclosure may be combined with each other if there is no contradiction.

It should be noted that similar numerals and letters refer to similar items in the following accompanying drawings. Once an item is defined in one accompanying drawing, the item does not require further discussion in subsequent accompanying drawings.

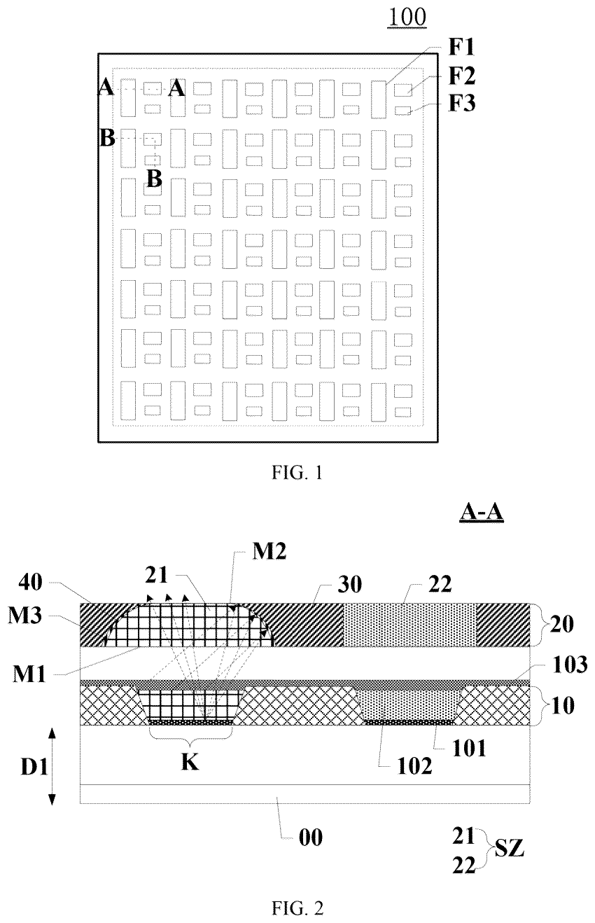

FIG. 1 illustrates a schematic diagram of a display panel consistent with various embodiments of the present disclosure. FIG. 2 illustrates an AA cross-sectional view of the display panel in FIG. 1. In one embodiment, a display panel 10 includes a substrate 00, a light-emitting layer 10 on side of the substrate 00, a color filter layer 20 on a side of the light-emitting layer 10 away from the substrate 00. The light-emitting layer 10 includes a plurality of pixel openings, the color filter layer 20 includes a plurality of color resists SZ, and a light-shielding layer 30 is filled between adjacent color resists SZ. Along a first direction D1, a color resists SZ overlaps a pixel opening K. The first direction D1 is perpendicular to a plane where the substrate 00 is located.

A color resist SZ includes a first surface M1 and a second surface M2 oppositely arranged along the first direction, and a first side M3 connecting the first surface M1 and the second surface M2. The light-shielding layer 30 covers the first side M3, and the first surface M1 is between the second surface M2 and the substrate 00. The color resist includes a first color resist 21. In the first color resist 21, along the first direction D1, an orthographic projection of the first side M3 to the substrate 00 overlaps an orthographic projection of the first surface M1 to the substrate 00. The display panel further includes reflective layers 40 between the light-shielding layers 30 and the first sides M3 of the first color resists 21. Optionally, a reflective layer 40 can be formed by coating a highly reflective material or a denser inorganic material on the first side M3 of the first color resist 21.

It should be noted that FIG. 1 only uses a display panel of a rectangular structure as an example for illustration and does not limit an actual structure of the display panel. In some other embodiments, the display panel may also be embodied in another shape, such as a circle, a rectangle with rounded corners, or another non-rectangular shape. FIG. 1 only schematically illustrates an arrangement form of sub-pixels in a display panel and does not limit an actual arrangement of sub-pixels. FIG. 2 only illustrates a relative positional relationship among the substrate 00, the light-emitting layer 10, and the color filter layer 20 in the display panel, does not represent an actual film layer structure of the display panel, and does not limit an actual thickness of each film layer. Feasible embodiments of each film layer in the display panel will be described subsequently.

Referring to FIG. 1 and FIG. 2, in the display panel provided by one embodiment, the color filter layer 20 is introduced on a side of the light-emitting layer 10 away from the substrate 00. The color filter layer 20 includes a color resist and a light-shielding layer 30, the light-shielding layer 30 defines a plurality of pixel openings K, and a color resist SZ fills a pixel opening K. Along the first direction D1, a color resist SZ is arranged in one-to-one correspondence with a pixel opening K, that is, a color resist SZ is arranged above each pixel opening K in the display area, so that light emitted by a light-emitting material layer in the pixel opening K can be emitted through the color resist SZ above the pixel opening K.

In the embodiment, when the color filter layer 20 is introduced on the side of the light emitting layer 10 away from the substrate 00, the color resist SZ in the color filter layer 20 can filter the light emitted by the light emitting material layer in the pixel opening K, and a color purity is higher, which is conducive to improving a display effect. In addition, the light-shielding layer 30 in the color filter layer 20 can absorb ambient light and avoid reflection on the display panel from affecting a display effect when the ambient light irradiates on the display panel, thereby improving an anti-reflection capability of the display panel.

Referring to FIG. 2, the color resist SZ in the color filter layer 20 includes a first surface M1 and a second surface M2 oppositely arranged along a first direction, and a first side M3 connecting the first surface M1 and the second surface M2. The first surface M1 is between the second surface M2 and the light emitting layer 10. In the first color resist 21, the orthographic projection of the first side M3 to the substrate 00 overlaps the orthographic projection of the first surface M1 to the substrate 00, so that part of light with a large viewing angle emitted by the light-emitting material layer in the pixel opening K corresponding to the first color resist 21 is emitted to the first side M3. In a related art, light with a large viewing angle emitted by the light-emitting material layer is blocked or absorbed by the light-shielding layer and cannot be emitted from a light-emitting surface of the display panel. In other words, light with a large viewing angle emitted by the light-emitting material layer cannot be utilized. In the embodiment, since the reflective layer 40 is arranged between the first side M3 of the first color resist 21 and the light-shielding layer 30, when light with a large viewing angle emitted by the light-emitting material layer in the pixel opening K hits the first side M3 of the first color resist 21, the reflective layer 40 arranged on the first side M3 can further reflect light with a large viewing angle emitted by the light-emitting material layer back into the pixel opening K. After being reflected by other film layers in the pixel opening, at least part of the light can be emitted to the light-emitting surface of the display panel, which is equivalent to effectively utilizing the light that could not be emitted from the light-emitting surface of the display panel and improving a performance from the first color. An amount of light emitted from the pixel opening corresponding to the first color resist to the light-emitting surface of the display panel is increased, thereby effectively improving an overall light-emitting efficiency of the display panel.

Referring to FIG. 2, in one optional embodiment, in the light-shielding layer 30, a surface covering the first side M3 of the first color resist 21 has a curved structure.

Specifically, the embodiment shown in FIG. 2 shows that the first side M3 of the first color resist 21 is an arc surface. Accordingly, the reflective layer 40 and the light-shielding layer 30 covering the first side M3 are also curved. When the reflective layer 40 has a curved surface structure, more light with a large viewing angle emitted by the light-emitting material layer in the pixel opening K towards the light-shielding layer 30 above the pixel opening K can be incident on the reflective layer 40, which is conducive to increasing an amount of light reflected to the pixel opening through the reflective layer 40, in turn increasing an amount of light reflected to the light-emitting surface of the display panel through the pixel opening, and improving an overall light-emitting efficiency of the display panel.

Referring to FIG. 2, in one optional embodiment, the light-emitting layer 10 includes anodes 101, light-emitting material layers 102 and a cathode 103. The light-emitting material layers 102 are filled in pixel openings K. The anodes 101 are on sides of the light-emitting material layers 102 facing the substrate 00, and the cathode 103 is on sides of the light-emitting material layers 102 away from the substrate 00. A surface of the light-shielding layer 30 covering the first side M3 has a concave mirror structure, and a focus of the concave mirrors are on a surface of an anode 101 facing the cathode 103.

Specifically, in the embodiment, the display panel may be a display panel using an organic light-emitting diode display technology, that is, an OLED display panel. Upper and lower sides of the light-emitting material layer 102 in the light-emitting layer 10 are respectively arranged with an anode 101 and a cathode 103. When appropriate voltages are provided to the anode 101 and the cathode 103 respectively, cavities in the anode 101 and electrons in the cathode 103 combine in the light-emitting material layer 102 to generate bright light. Compared with thin film field effect transistor liquid crystal displays, OLED display devices have characteristics of high visibility and high brightness, and are more power-saving, lighter and thinner.

The reflective layer 40 is arranged between the first side M3 of the first color resist 21 and the light-shielding layer 30. When the light-shielding layer 30 has concave mirror structures, the reflective layer 40 arranged between the light-shielding layer 30 and the first side M3 of the first color resist 21 also has a concave mirror structure. When light with a large viewing angle emitted by the light-emitting material layer 102 in the pixel opening irradiates on the reflective layer 40 of the concave mirror structure, the reflective layer 40 reflects part of light with a large viewing angle. In one embodiment, a focus of the concave mirror is arranged on a surface of the anode 101 of the light-emitting layer 10 facing the cathode 103, and light reflected by the concave mirror will be reflected to the anode 101 in the light-emitting layer 10. Optionally, the anode 101 includes a metal material. When the light is irradiated on the anode 101, the anode 101 can reflect light, and can reflect at least part of light reflected on the anode 101 through the reflective layer 40 to the light-emitting surface of the display panel, so that the at least part of light reflected on the anode 101 through the reflective layer 40 to the light-emitting surface of the display panel can be effectively used, and an overall light extraction efficiency of the display panel can be effectively improved. When a surface of the light-shielding layer 30 in contact with the reflective layer 40 is arranged as a concave mirror structure, compared with a surface of a planar structure, the concave mirror structure can focus light in a larger range. Therefore, more light with a large viewing angle can be focused on the anode, which is conducive to increasing an amount of light reflected by the anode to the light-emitting surface of the display panel and improving a light-emitting efficiency of the display panel.

It should be noted that, when a distance between the surface of the light-shielding layer 30 facing the anode and the anode 101 is fixed, and the focus of the concave mirror is on the surface of the anode 101, a radius of the concave mirror structure can be calculated by the formula f=R/2 by combining a focal length of the concave mirror and a radius of curvature.

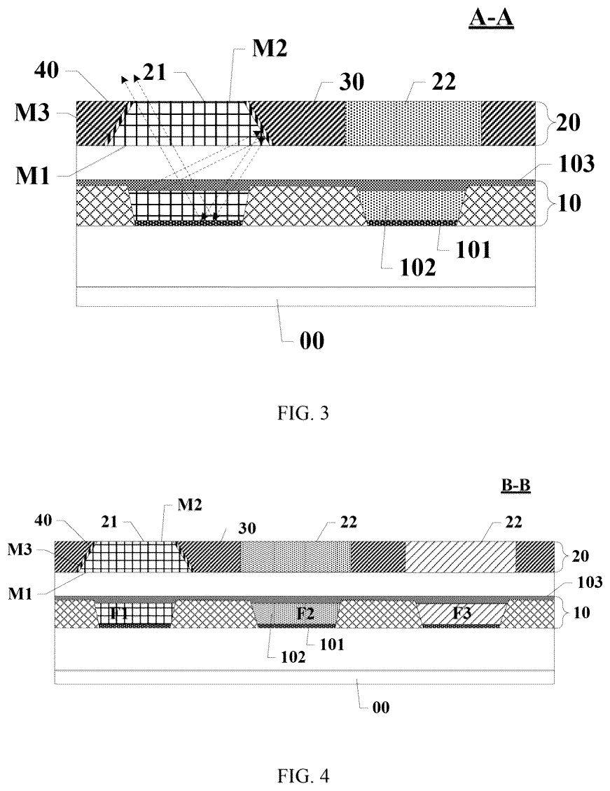

Optionally, when the reflective layer is a concave mirror structure, a focal point of the concave mirror structure is on a surface of the anode but does not coincide with a center point of the anode, to avoid that light reflected to the center point of the anode cannot be emitted from the first color resist. The center point of the anode is a center point of the anode exposed by the pixel opening. For example, when the anode is circular, the center point is the center of the circle. FIG. 3 illustrates another AA cross-sectional view of the display panel in FIG. 1. One embodiment shows another possible structure of the first color resist 21, a difference of the embodiment in FIG. 3 from the embodiment in FIG. 2 is that the first side M3 of the first color resist 21 is a planar structure.

Referring to FIG. 3, in one optional embodiment, the surface of the light-shielding layer 30 in contact with the reflective layer 40 is a first slope, and an angle between the first slope and the first surface M1 of the first color resist 21 is an acute angle. It should be noted that the first inclined surface mentioned in the embodiment may be a plane or an arc surface. The embodiment shown in FIG. 3 takes the first slope as a plane as an example for illustration. When the first slope is an arc, the angle between the first slope and the first surface refers to an angle between a tangent of the first arc surface and the first surface.

Specifically, the surface of the light-shielding layer 30 in contact with the reflective layer 40 is the first slope. Since the reflective layer 40 is formed between the first side M3 of the first color resist 21 and the light-shielding layer 30, the first slope described above is parallel to the first side M3 of the first color resist 21 and a value of an angle between the first slope and the first surface M1 of the first color resist 21 is equal to the value of the angle between the first side M3 of the first color resist 21 and the first surface M1 of the first color resist 21. In one embodiment, when an angle between the first slope and the first surface M1 of the first color resist 21 is arranged as an acute angle, the reflective layer 40 is inclined toward the direction of the corresponding pixel opening, so that light with a large viewing angle emitted by the light-emitting material layer 102 in the pixel opening can be directed to the reflective layer 40, directed to the pixel opening after being reflected by the reflective layer 40, and directed to the light-emitting surface of the display panel after being reflected by the anode 101 in the pixel opening, which is also conducive to improving the overall light extraction efficiency of the display panel.

FIG. 4 illustrates a BB cross-sectional view of the display panel in FIG. 1. One embodiment illustrates a corresponding relationship between pixel openings and color resist when the display panel includes light-emitting material layers of three different colors.

In one optional embodiment, the light emitting layer 10 includes light emitting material layers 102, and the light emitting material layers 102 include a first color light emitting material layer F1, a second color light emitting material layer F2 and a third color light emitting material layer F3. A same pixel opening is filled with a light-emitting material layer 102 of a single color. A light-emitting efficiency of the first color light-emitting material layer F1 is lower than a light-emitting efficiency of the second color light-emitting material layer F2 and is lower than a light-emitting efficiency of the third color light-emitting material layer F3.

The color resists also include a second color resist 22. In the second color resist 22, along the first direction, the orthographic projection of the first side M3 to the substrate 00 does not overlap the orthographic projection of the first surface M1 to the substrate 00. It should be noted that, assuming that the orthographic projection of the first surface M1 to the substrate 00 includes contour lines and a central area defined by the contour lines, the non-overlap mentioned herein means that the orthographic projection of the first side M3 to the substrate does not overlap the central region described above. That is, an end of the first side M3 away from the first surface is not inclined towards a central area of the first surface M1. Optionally, in the second color resist 22, the first side M3 is perpendicular to the first surface M1.

The first color resist 21 is disposed above the pixel opening corresponding to the first color light-emitting material layer F1. The second color resist 22 is above the pixel opening corresponding to at least one of the second color light emitting material layer F2 and the third color light emitting material layer F3. In one embodiment, the second color resist 22 is arranged directly above the corresponding pixel openings of the second color light emitting material layer F2 and the third color light emitting material layer F3 as an example for illustration.

Specifically, in the embodiment, the color filter layer 20 of the display panel includes not only the first color resist 21 but also the second color resist 22. When the light-emitting colors of the light-emitting material layers 102 in the light-emitting layer 10 are different, due to material differences, the luminous efficiencies of the light-emitting material layers 102 of different colors are not completely same. In one embodiment, among the first color light emitting material layer F1, the second color light emitting material layer F2 and the third color light emitting material layer F3, the light emitting efficiency of the first color light emitting material layer F1 is the lowest. The luminous efficiencies of the second color light-emitting material layer F2 and the third color light-emitting material layer F3 are both higher than the first color light-emitting material layer F1. Therefore, in one embodiment, the first color resist 21 is arranged directly above the pixel opening where the first color light-emitting material layer F1 is located, and the second color resist 22 is arranged directly above the pixel opening where the second color light-emitting material layer F2 and the third color light-emitting material layer F3 are located. Among the light emitted by the first color light-emitting material layer F1 with low light-emitting efficiency, at least part of the light with a large angle will be able to strike the reflective layer 40 on the first side M3 of the first color resist 21. The light reflected by the reflective layer 40 is further reflected back into the pixel opening, and emitted from the light-emitting surface of the display panel after being reflected by the anode 101 corresponding to the pixel opening, which is conducive to improving the light extraction efficiency of the first color luminescent material with low light-emitting efficiency to balance the light-emitting efficiency difference between the first color light-emitting material layer, the second color light-emitting material layer and the third color light-emitting material layer, while improving an overall light output efficiency of the display panel, it is also beneficial to improve an overall display effect of the display panel.

Optionally, in one embodiment, the first color light-emitting material layer F1 is a blue light-emitting material layer 102, the second color light-emitting material layer F2 is a red light-emitting material layer 102 and the third color light-emitting material layer F3 is a blue light-emitting layer 10 material layer.

Optionally, the first side M3 of the second color resist 22 is perpendicular to the first surface M1 and the second surface M2 thereof. That is, the second color resist 22 can be configured with a conventional structure, and no special design is required for the first side M3, which is conducive to simplifying an overall forming process of the color filter layer 20.

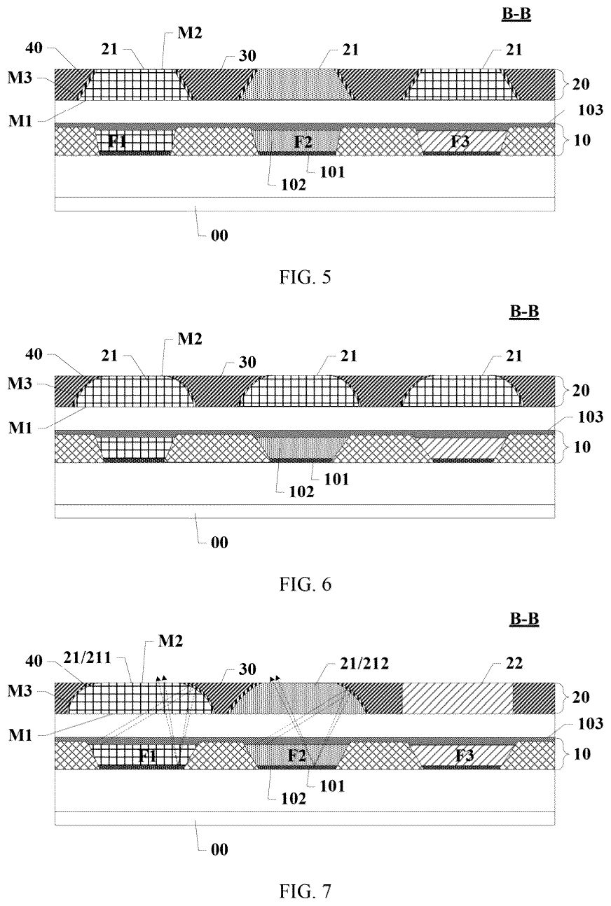

FIG. 5 illustrates another BB cross-sectional view of the display panel in FIG. 1. One embodiment shows another feasible structure of the color filter layer 20 in the display panel.

Referring to FIG. 5, in one optional embodiment, the light emitting layer 10 includes light emitting material layers 102, and the light emitting material layers 102 include a first color light emitting material layer F1, a second color light emitting material layer F2 and a third color light emitting material layer F3. A same pixel opening is filled with light-emitting material layer 102 of a single color. The color resists corresponding to pixel openings of the first color light emitting material layer F1, the second color light emitting material layer F2 and the third color light emitting material layer F3 are all the first color resists 21. It should be noted that the color resists corresponding to the pixel openings of the light emitting material layers 102 of different colors are all the first color resists 21. The first color resists 21 herein only reflects a shape and do not limit colors of the color resists corresponding to a light emitting material layers 102 of different colors. Optionally, colors of the first color resists 21 corresponding to pixel openings of light-emitting material layers 102 of different color are different, and a color of the light-emitting material layer 102 in a same pixel opening is same as a color of a corresponding first color resist 21.

In the embodiment, color resists are arranged directly above the pixel openings of the light emitting material layers 102 of different colors are all the first color resists 21 and the first side M3 of each first color resist 21 is taken as an example for illustration. However, the shape of the first side M3 of the first color resist 21 is not limited. Referring to FIG. 6, in some other embodiments, the first side M3 of the first color resist 21 may also be embodied as a concave mirror structure. FIG. 6 illustrates another BB cross-sectional view of the display panel in FIG. 1. The embodiments shown in FIG. 5 and FIG. 6 are only illustrated by taking a same shape of the first side M3 of the first color resist 21 corresponding to light-emitting elements of different colors as an example, which is not limited herein. In other embodiments, when the first color resists 21 are introduced into the display panel for pixel openings corresponding to light-emitting material layers 102 of different colors, shapes of the first sides M3 of the first color resists 21 may also be different. For example, the first sides M3 of part of the first color resists 21 are embodied as arc surfaces, and the first side M3 of part of the first color resists 21 are embodied as inclined planes and the like.

When the first color resists 21 are introduced directly above the pixel openings corresponding to the first color light-emitting material layer F1, the second color light-emitting material layer F2 and the third color light-emitting material layer F3, due to a reflection effect of the reflective layer 40 arranged on the first surface M1 of the first color resist 21, at least part of the light emitted by the first color light emitting material layer F1, the second color light emitting material layer F2 and the third color light emitting material layer F3 can be directed to the reflective layer 40, reflected by the reflective layer 40, returned to the pixel opening, reflected by the anode 101 corresponding to the pixel opening and reflected to the light-emitting surface of the display panel, thereby improving light extraction rate of the light emitted by each color light-emitting material layer, which is more conducive to improving the overall light extraction efficiency of the display panel.

FIG. 7 illustrates another BB cross-sectional view of the display panel in FIG. 1. In one embodiment, the first color resist 21 is arranged above the pixel openings of the first color light-emitting material layer F1 and the second color light-emitting material layer F2.

Referring to FIG. 7, in one optional embodiment, the light emitting layer 10 includes a light emitting material layer 102, the light emitting material layer 102 includes a first color light emitting material layer F1 and a second color light emitting material layer F2. A same pixel opening is filled with a light emitting material layer 102 of a single color. The light-emitting efficiency of the first color light-emitting material layer F1 is lower than the light-emitting efficiency of the second color light-emitting material layer F2.

The first color resist 21 is respectively arranged above the pixel opening corresponding to the first color light-emitting material layer F1 and above the pixel opening corresponding to the second color light-emitting material layer F2. The first color resist 21 corresponding to the first color light-emitting material layer F1 is the first sub-color resist 211. The first color resist 21 corresponding to the second color light-emitting material layer F2 is a second sub-color resist 212.

The first side M3 of the first color resist 21 is a plane, an angle between the first side M3 of the first sub-color resist 211 and the first surface M1 is α1, an angle between the first side M3 of the second sub-color resist 212 and the first surface M1 is α2, and α1<α2.

Specifically, the embodiment is described by taking the first side M3 of the first color resist 21 as an inclined plane as an example. When the first color resist 21 is arranged directly above the corresponding pixel openings of the first color light-emitting material layer F1 and the second color light-emitting material layer F2, assuming that the first color resist 21 corresponding to a pixel opening of the first color light-emitting material layer F1 is the first sub-color resist 211, the first color resist 21 corresponding to a pixel opening of the second color light-emitting material layer F2 is a second sub-color resist 212. Through the reflection effects of the reflective layers 40 on the first sides M3 of the first sub-color resist 211 and the second sub-color resist 212, an amount of light emitted by the first color light-emitting material layer F1 and the second color light-emitting material layer F2 is increased, thereby improving the overall light extraction efficiency of the display panel.

In addition, in one embodiment, the light-emitting efficiency of the first color light-emitting material layer F1 is lower than the light-emitting efficiency of the second color light-emitting material layer F2. Optionally, an area of the pixel opening corresponding to the first color light-emitting material layer F1 is larger than an area of the pixel opening corresponding to the second color light-emitting material layer F2. By increasing the area of the pixel opening corresponding to the light-emitting material layer with a lower light-emitting efficiency, an amount of light emitted by the first color light-emitting material layer in the pixel opening can be increased to a certain extent. In addition, in the present disclosure, angles between the first surface M1 and the first side M3 of the first color resist 21 corresponding to the first color light-emitting material layer F1 and the second color light-emitting material layer F2 are designed differently, so that an angle α1 corresponding to the first sub-color resist 211 is smaller than an angle α2 corresponding to the second sub-color resist 212. When α2 is large, part of light with a large viewing angle emitted by the second color light-emitting material layer F2 is irradiated to the reflective layer on the first side of the second sub-color resist 212, and after being reflected by the reflective layer, a reflection point at the anode is closer to a center of the anode. When α1 is small, part of light with a large viewing angle emitted by the light-emitting material layer F1 of the first color travels to the reflective layer on the first side of the first sub-color resist 211, and after the part of light with a large viewing angle is reflected by the reflective layer, the reflection point at the anode is far from the center of the anode. Therefore, after being reflected by the anode, light emitted from the first sub-color resist 211 is closer to a normal viewing angle, and light emitted from the second sub-color resist 212 is farther away from the normal viewing angle. That is, by arranging α1<α2, an amount of light emitted by the first color light-emitting material layer F1 at a front viewing angle is increased, and brightness at the front viewing angle is improved, which is conducive to further compensating for a brightness difference caused by a difference in light-emitting efficiency between the first color light-emitting material layer F1 and the second color light-emitting material layer F2, and improving an overall display brightness uniformity and the display effect of the display panel.

Optionally, in one embodiment, the first color light-emitting material layer F1 is a blue light-emitting material layer 102, and the second color light-emitting material layer F2 is a red light-emitting material layer or a green light-emitting material layer.

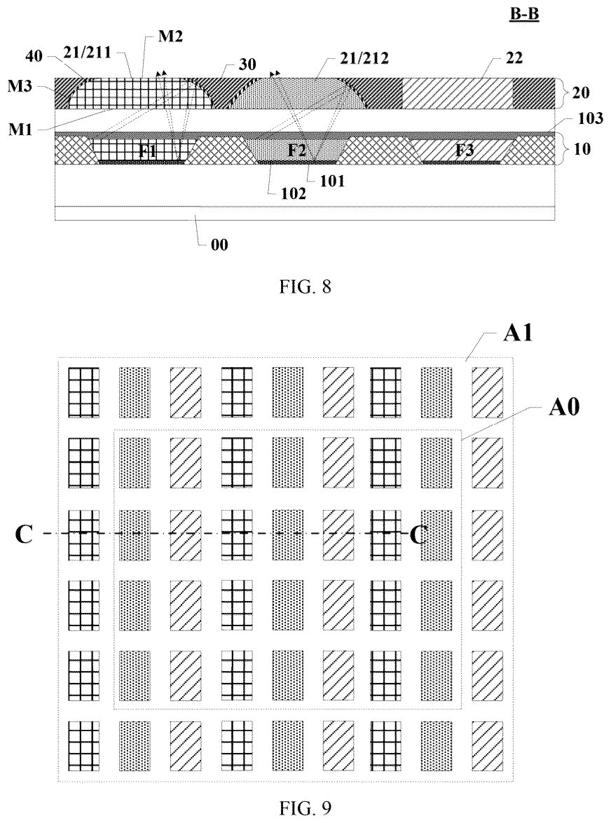

FIG. 8 illustrates another BB cross-sectional view of the display panel in FIG. 1. In one embodiment, the first color resists 21 are arranged above pixel openings of the first color light emitting material layer F1 and the second color light emitting material layer F2.

Referring to FIG. 8, in one optional embodiment, the light-emitting material layers 102 include a first color light-emitting material layer F1 and a second color light-emitting material layer F2. A same pixel opening is filled with a light-emitting material layer 102 of a single color. The light-emitting efficiency of the first color light-emitting material layer F1 is lower than the light-emitting efficiency of the second color light-emitting material layer F2.

The first color resists 21 are respectively arranged above the pixel opening corresponding to the first color light-emitting material layer F1 and above the pixel opening corresponding to the second color light-emitting material layer F2. The first color resist 21 corresponding to the first color light-emitting material layer is the first sub-color resist 211. The first color resist 21 corresponding to the second color light-emitting material layer is the second sub-color resist 212.

The first side M3 of the first color resist 21 is an arc surface, a radius of the first side M3 of the first sub-color resist 211 is s1, a radius of the first side M3 of the second sub-color resist 212 is s2, and s1<s2.

Specifically, the embodiment is described by taking the first side M3 of the first color resist 21 as a concave mirror structure as an example. When the first color resist 21 of a concave mirror structure is arranged directly above pixel openings corresponding to the first color light-emitting material layer F1 and the second color light-emitting material layer F2, assuming that the first color resist 21 corresponding to the pixel opening of the first color light-emitting material layer F1 is the first sub-color resist 211, the first color resist 21 corresponding to the pixel opening of the second color light-emitting material layer F2 is the second sub-color resist 212. Through reflection effects of the reflective layers 40 on the first sides M3 of the first sub-color resist 211 and the second sub-color resist 212, an amount of light emitted by the first color light-emitting material layer F1 and the second color light-emitting material layer F2 is increased, thereby improving the overall light extraction efficiency of the display panel.

In one embodiment, the light-emitting efficiency of the first color light-emitting material layer F1 is lower than the light-emitting efficiency of the second color light-emitting material layer F2. The brightness difference between the first color light emitting material layer and the second color light emitting material layer can be reduced by increasing an area of the pixel opening where the first color light emitting material layer is located. Referring to FIG. 8, based on the above, radii of the concave mirror structures corresponding to the first sides of the first sub-color resist 211 and the second sub-color resist 212 are designed differently. When the curvature s1 of the first side of the first sub-color resist 211 corresponding to the first color light-emitting material layer F1 with a lower light-emitting efficiency is arranged smaller, part of light with a large viewing angle hits the reflective layer on the first side and is reflected by the reflective layer, and the reflection point at the anode is far from the center of the anode. When the curvature s2 of the first side of the second sub-color resist 212 corresponding to the second color light-emitting material layer F2 with a higher light-emitting efficiency is arranged smaller, part of light with a large viewing angle hits the reflective layer on the first side and is reflected by the reflective layer, and the reflection point at the anode is closer to the center of the anode. When the reflection point is far from the center of the anode, the light reflected by the anode is closer to the normal viewing angle. When the reflection point is closer to the center of the anode, more of the light reflected by the anode is light with a large viewing angle. arranging s1<s2 in the embodiment is equivalent to increasing an amount of light at a front view angle emitted from the first sub-color resist 211 corresponding to the first color light-emitting material layer F1 with a lower light-emitting efficiency, which is conducive to improving brightness of the pixel opening corresponding to the first color light-emitting material layer F1 when viewed from a front view angle, further balancing the difference in display brightness caused by the difference in light-emitting efficiency between the first color light-emitting material layer and the second color light-emitting material layer, and improving the overall display brightness uniformity and the display effect of the display panel.

Referring to FIG. 1, FIG. 7 and FIG. 8, in one optional embodiment, the area of the pixel opening corresponding to the first color light-emitting material layer F1 is larger than the area of the pixel opening corresponding to the second color light-emitting material layer F2.

An area of the pixel opening can be regarded as an area corresponding to an opening on a side of the pixel opening adjacent to the anode 101 in the light emitting layer 10. When the light-emitting efficiency of the first color light-emitting material layer F1 is lower than the light-emitting efficiency of the second color light-emitting material layer F2, in the embodiment, appropriately increasing the area of the pixel opening corresponding to the first color light-emitting material layer F1 can compensate, to a certain extent, for a difference in an amount of light emitted by the first color light-emitting material layer F1 and the second color light-emitting material layer F2 due to a difference in light-emitting efficiency, and increase the light output of the first color light-emitting material layer F1. By arranging the first side M3 of the first color resist 21 corresponding to the first color light-emitting material layer F1 as an arc structure or an inclined planar structure, and differentially designing a radius of the arc-shaped structure or an inclination of the planar structure, an amount of light emitted from the first sub-color resist corresponding to the first color light-emitting material layer F1 is further increased in the normal viewing angle to balance amounts of light emitted by the first color light-emitting material layer F1 and the second color light-emitting material layer F2, which is conducive to further improving the overall light output and the display effect of the display panel.

Optionally, in the embodiment, the first color light-emitting material layer F1 is a blue light-emitting material layer, and the second color light-emitting material layer F2 is a red light-emitting material layer or a green light-emitting material layer.

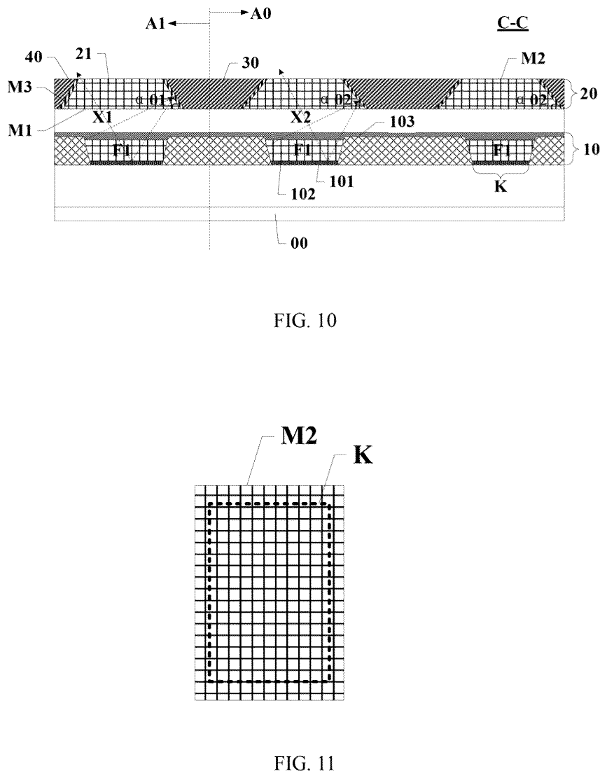

FIG. 9 illustrates a schematic diagram of an arrangement of sub-pixels in a display panel consistent with various embodiments of the present disclosure. FIG. 10 illustrates a CC cross-sectional view of the display panel in FIG. 9.

Referring to FIG. 9 and FIG. 10, in one optional embodiment, a display area of the display panel includes a central area A0 and an edge area A1, and the edge area A1 is arranged at edges of the display area around the central area A0. For a same light color, in the edge area A1, an angle between the first side M3 of the first color resist 21 and the first surface M1 is α01, in the central area A0, an angle between the first side M3 of the first color resist 21 and the first surface M1 is α02, and α01>α02.

It should be noted that FIG. 9 only schematically shows a pixel arrangement in the display panel and does not limit an actual pixel arrangement structure in the display panel. In some other embodiments, the display panel may also adopt other forms of pixel arrangement structures. To clearly show an arranging difference of the first color resists 21 corresponding to the pixel openings of a same light-emitting color in the central area A0 and the edge area A1, the cross-sectional view of FIG. 10 only shows the first color resists 21 corresponding to the pixel openings of the same light-emitting color and does not show pixel openings and corresponding color resists of other light-emitting colors.

Optionally, the edge area A1 mentioned in the embodiment refers to an area where an outermost circle of pixel openings in the display area is located. The central area A0 can be regarded as other areas except the edge area A1, and the central area A0 is surrounded by the edge area A1.

For a same light-emitting color, in one embodiment, the first side M3 of the first color-resistor 21 corresponding to the pixel opening located in the edge area A1 and the first color-resistor 21 corresponding to the pixel opening located in the central area A0 are differentially designed, so that the angle α01 between the first side M3 of the first color resist 21 in the edge area A1 and the first surface M1 is greater than the angle α02 between the first side M3 of the first color resist 21 and the first surface M1 in the central area A0. Referring to FIG. 10, the angle α01 and angle α02 respectively represent angles between the first side and the first surface of the first color resist. When light with a same large viewing angle hits the reflective layer of a side wall of the first color resist corresponding to the angle α01 and the angle α02, in light reflected by the reflective layer to the anode and further reflected by the anode, light with a large viewing angle reflected by the reflective layer corresponding to the larger angle α01 is a first light X1, and light with a large viewing angle reflected by the reflective layer corresponding to the smaller angle α02 is a second light X2. When α01 is larger, light reflected by the reflective layer is closer to the center of the anode, more of the first light X1 reflected by the anode is emitted to an area with a large viewing angle. When α02 is small, light reflected by the reflective layer is farther away from the center of the anode, the second light X2 emitted by the anode is closer to a normal viewing angle. Therefore, when the angle between the first side M3 and the first surface M1 of the first color resist 21 is larger, a corresponding pixel opening emits more light from a position away from the center of the anode. When the angle between the first side M3 and the first surface M1 of the first color resist 21 of the edge area A1 is arranged larger, the light-emitting material layer 102 in the pixel opening of the edge area A1 emits more light from the position away from the center of the anode. That is, more light is emitted to a frame area outside the edge area A1 of the display panel, which is conducive to visually shrinking a frame width.

FIG. 11 illustrates a top view relationship diagram of the pixel opening K and the second surface M2 of a color resist. Referring to FIG. 10 and FIG. 11, in one optional embodiment, in the color resist arranged corresponding to the pixel opening K, an area of the orthographic projection of the second surface M2 to the substrate 00 is greater than or equal to the area of the pixel opening K.

The first color resist 21 includes a first surface M1 and a second surface M2 oppositely arranged along the first direction. The first surface M1 is a surface adjacent to the light emitting layer 10, and the second surface M2 is a surface on a side of the first surface M1 away from the light emitting layer 10. In the embodiment, an orthographic projection of the first side M3 of the first color resist 21 to the substrate 00 overlaps an orthographic projection of the first surface M1 to the substrate 00, so that an area of the orthographic projection of the first surface M1 to the substrate 00 is larger than the area of the orthographic projection of the second surface M2 to the substrate 00, i.e., the second surface M2 is a surface with a smaller projected area in the first color resist 21. The pixel opening K is an opening penetrating the pixel definition layer along the first direction. The pixel opening includes an opening adjacent to the anode 101 and another opening on a side of the opening away from the anode 101. In the embodiment, the area of the pixel opening referred to is an area of the opening adjacent to the anode 101 among the pixel openings. In the embodiment, when the first color resist 21 is arranged directly above the pixel opening, the area of the orthographic projection of the second surface M2 to the substrate 00 is arranged to be greater than or equal to the area of the pixel opening, so that edges of the orthographic projection of the second surface M2 to the substrate 00 coincide with an orthographic projection of the opening adjacent to the anode 101 in the pixel opening to the substrate 00, or edges of the orthographic projection of the second surface M2 to the substrate 00 is at a periphery of edges of the orthographic projection of the opening adjacent to the anode 101 to the substrate 00 in the pixel opening, to prevent the light-shielding layer 30 from blocking the pixel opening, so that more light emitted by the light-emitting material layer 102 in the pixel opening can be emitted through the first color resist 21. is conducive to improving an overall light output of the display panel.

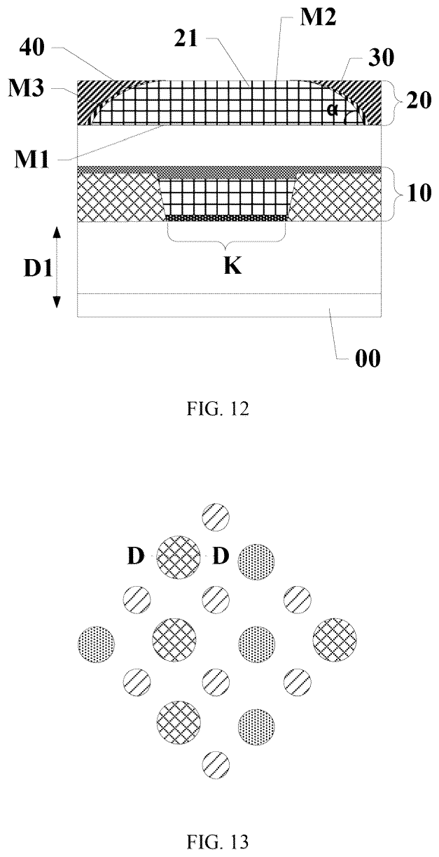

FIG. 12 illustrates a schematic diagram of a relative positional relationship between the first color resist 21 and a pixel opening in a display panel consistent with various embodiments of the present disclosure.

Referring to FIG. 12, in one optional embodiment, In the first color resist 21, an angle between the first side M3 and the first surface M1 is a, and 40°≤α≤60°. It should be noted that, when the first side M3 is an inclined plane, the angle α is an angle between the plane where the first side M3 is located and the first surface M1. When the first side M3 has an arcuate structure, the angle α is an angle between a tangent of a junction between the arcuate surface and the first surface M1 and the first surface M1.

Specifically, when the angle between the first side M3 and the first surface M1 of the first color resist 21 is arranged to be small, for example, less than 40°, an area of the orthographic projection of the second surface M2 in the first color resist 21 to the substrate 00 may be smaller than an area of the orthographic projection of the opening adjacent to the anode 101 in the pixel opening to the substrate 00. That is, the light-shielding layer 30 may extend toward a direction of the pixel opening, causing the pixel opening of the light-shielding layer 30 to block and affect an amount of light emitted from the pixel openings. However, if the angle between the first side M3 and the first surface M1 is arranged relatively large, for example greater than 60°, an overlapping area of the first side M3 of the first color resist 21 and the orthographic projection of the first surface M1 onto the substrate 00 becomes smaller. An amount of light at a large angle emitted by the light-emitting material layer 102 in the pixel opening that can be received by the reflective layer 40 on the first side M3 decreases, which also affects the overall light output of the display panel. Therefore, in the embodiment, arranging the angle between the first side M3 and the first surface M1 in the first color resist 21 to be 40°≤α≤60°, can not only avoid blocking the pixel opening by the light-shielding layer 30, ensure the aperture ratio of the display panel, but also ensure that more light with a large viewing angle emitted by the light-emitting material layer 102 in the pixel opening can be directed to the reflective layer 40 of the first side M3, which is conducive to increasing an amount of light reflected by the reflective layer 40 to the anode 101 of the pixel opening and further directed to the light-emitting surface of the display panel, thereby increasing the overall light output of the display panel.

Optionally, 45°≤α≤50°, or 50°≤α≤55°.

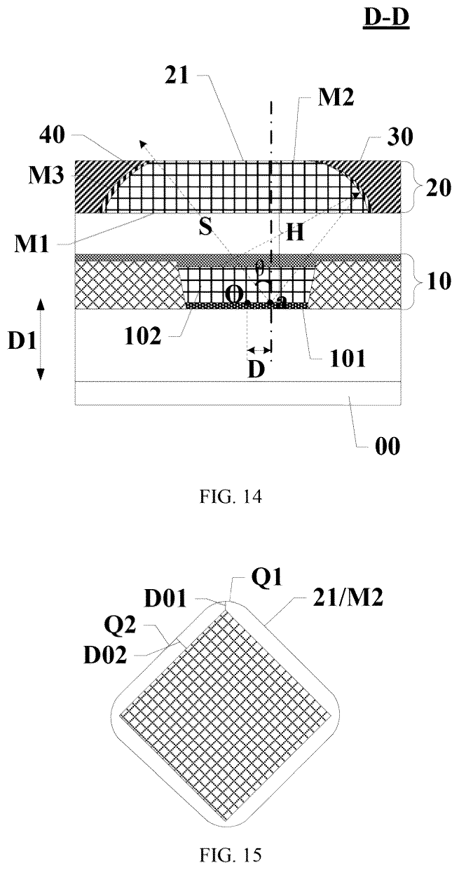

FIG. 13 illustrates another schematic diagram of an arrangement of sub-pixels in a display panel consistent with various embodiments of the present disclosure. FIG. 14 illustrates a DD cross-sectional view of the display panel in FIG. 13. In one embodiment, the display panel is illustrated by taking the pixel opening with a circular structure as an example. When an orthographic projection of the pixel opening to the substrate 00 is circular, edges of an orthographic projection of the first color resist 21 arranged directly above the pixel opening on the substrate 00 is also circular.

Referring to FIG. 13 and FIG. 14, in one optional embodiment, the light emitting layer 10 includes anodes 101, light emitting material layers 102 and a cathode 103. The light-emitting material layers 102 are filled in the pixel openings. The anodes 101 are on sides of the light emitting material layers 102 facing the substrate 00, and the cathode 103 is on sides of the light emitting material layers 102 away from the substrate 00.

At least part of light emitted by the light-emitting material layer 102 is directed to the reflective layer 40 and is reflected by the reflective layer 40 to the reflection point “a” on the anode 101, Light reflected by the reflection point “a” is a first reflected light. An angle between the first reflected light and a normal of the plane where the anode 101 is located is θ, θ≤arccos(H/S), H is a vertical distance between the reflection point and the second surface M2 of the first color resist 21, and S is a length of a line connecting the reflection point “a” and an edge of the light-shielding layer 30. The connecting line and the corresponding incident light are in the same plane and are in a same cross-section shown in FIG. 14.

Optionally, when the second surface M2 of the first color resist 21 and the orthographic projection of the pixel opening to the substrate 00 are both circular and are concentric circles, the reflective layer 40 reflects this part of the light to the anode 101 corresponding to the pixel opening. Assuming that the light reaches the reflection point a of the anode 101, the reflection effect of the anode 101 further reflects this part of the light. When θ≤arccos(H/S) is arranged, the light reflected by the anode 101 can be emitted from the second surface M2 of the first color resist 21, and then emitted from the light emitting surface of the display panel, which is conducive to increasing the overall light output of the display panel.

Referring to FIG. 14, in an optional embodiment, the distance between the reflection point and the center point of the anode 101 is D, and D>0.

In the present disclosure, along the first direction D1, the anode 101 overlaps the opening adjacent to the anode 101 in the pixel opening. That is, the pixel opening exposes the anode 101, and the center point of the anode 101 can be regarded as a center point of the anode 101 exposed by the pixel opening. Since the orthographic projection of the pixel opening to the substrate 00 is circular, the anode 101 exposed by the pixel opening is also circular, and the center point of the anode 101 can be regarded as the center of the anode 101 of the circular structure. In the embodiment, a distance between the reflection point and the center point of the anode 101 is arranged to be greater than 0, that is, the reflection point does not coincide with the center point of the anode 101, and the reflection point is at a periphery of the center point of the anode 101. Considering that if the reflection point coincides with the center of the anode 101, light reflected by the reflection point hits the reflective layer 40 on the first side M3 and cannot be emitted from the second surface M2 of the first color resist 21. Therefore, in the embodiment, the reflection point is arranged not to coincide with the central point of the anode 101, so that light reflected by the reflection point can be emitted from the second surface M2 of the first color resist 21, which is conducive to increasing an amount of light emitted through the second surface M2 of the first color resist 21, and increasing the overall light output of the display panel and a utilization rate of light emitted by a light-emitting material.

Referring to FIG. 14, in a cross-sectional view shown in FIG. 14, Assuming that light with a large viewing angle emitted by the light-emitting material layer is emitted from a left side of the central point “O” of the anode to the reflective layer in an upper right area of the central point of the anode, the reflection point “a” (i.e., a focus of the concave mirror) at which light is reflected by the reflective layer to the anode is on the right side of the center point “O” of the anode. That is, the reflective layer corresponding to light reflected to the reflection point and the reflection point of the light on the anode are on a same side of the central point “O” of the anode.

FIG. 15 illustrates a top view relationship diagram of a pixel opening and a second surface of a first color resist in a display panel. Referring to FIG. 12 and FIG. 15, the first color resist 21 overlaps the pixel opening K along the first direction D1, and the orthographic projection of the pixel opening K to the substrate is a first projection. The orthographic projection of the second surface M2 in the first color resist 21 to the substrate is a second projection. The second projection is on a periphery of the first projection. The first projection is a first polygon. The first polygon includes a first area Q1 and a second area Q2 adjacent to the first area Q1. The first area Q1 includes corners, and the second area Q2 includes straight-line edges. A minimum distance D01 between vertexes of the corners and the second projection is smaller than a minimum distance D02 between the straight-line edges of the second area Q2 and the second projection.

The pixel opening K with a polygonal structure is more conducive to improving an aperture ratio of the display panel compared to the pixel opening with a circular structure. In the embodiment, the first polygon of a shape of the pixel opening as a rhombus is taken as an example for illustration, but the shape of the pixel opening is not limited herein. In some other embodiments, the first polygon may also be embodied as another polygonal structure.

In the embodiment, the second projection corresponding to the second surface M2 is designed as follows: the minimum distance D01 between the vertexes of the corners of the first projection corresponding to the pixel opening is smaller than the minimum distance D02 between the straight-line edges in the second area Q2, which is equivalent to specially designing the first side of the first color resist at a corner of the first polygon, reducing a distance between the second projection and the corner, so that light at the corner in the pixel opening can be directed to the reflective layer on the first side of the first color resist. After being reflected by the reflective layer, light is emitted from the first color resist to avoid excessive diffraction of light at the first corner of the pixel opening, thereby increasing the light output of the display panel is increased and helping to improve the overall display of the display panel.

Referring to FIG. 12 and FIG. 15, in one optional embodiment, in the second projection corresponding to the second surface of the first color resist, at least edges adjacent to the corners are arc edges.

FIG. 15 shows a scheme in which the edges adjacent to the corners are curved edges in the second projection. When the reflective layer in the area of the edges adjacent to the corners is arranged in an arc-shaped structure, the reflective layer in the area of the edges adjacent to the corners can focus light in a wider range, so that more light with a large viewing angle corresponding to corner areas can be focused on the anode, which is more conducive to improving the light extraction efficiency of the display panel and avoiding excessive diffraction.

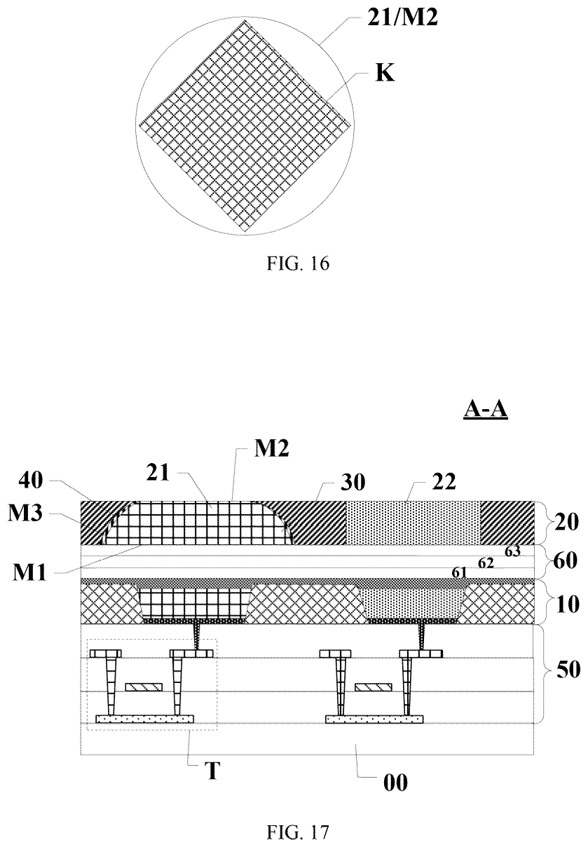

In some other embodiments, Referring to FIG. 16, an overall shape of the second projection can also be arranged as an arc. FIG. 16 illustrates another top view relationship diagram of a pixel opening and a second surface of a first color resist in a display panel. In one embodiment, a shape of the orthographic projection of the second surface M2 of the first color resist 21 to the substrate as a circle is taken as an example for illustration, which is more conducive to simplifying a forming process of the first color resist compared with other special-shaped structures.

FIG. 17 illustrates another AA cross-sectional view of the display panel in FIG. 1. In one optional embodiment, the display panel also includes a driving layer 50 and an encapsulation layer 60. Along the first direction, the driving layer 50 is between the substrate 00 and the light emitting layer 10, and the encapsulation layer 60 is between the light emitting layer 10 and the color filter layer 20. The driving layer 50 includes a driving transistor “T” electrically connected to the light emitting layer 10.

Referring to FIG. 17, in the embodiment, part of film layer structures in the display panel is refined. The driving layer 50 is arranged between the light emitting layer 10 and the substrate 00. The driving layer 50 includes a driving transistor “T”. The anode 101 in the light-emitting layer 10 is electrically connected to the driving transistor “T”, and the driving signal is obtained through the driving transistor “T”. It should be noted that FIG. 17 only shows the driving transistor “T” in the driving layer 50. Optionally, the driving layer 50 also includes other transistors. The encapsulation layer 60 is arranged between the light emitting layer 10 and the color filter layer 20. Optionally, the encapsulation layer 60 includes a first inorganic layer 61, an organic layer 62 and a second inorganic layer 63 stacked along the first direction. Encapsulation of the light-emitting layer 10 through a combination of the inorganic layer and the organic layer can isolate the light-emitting layer 10 from outside air and moisture and prevent the light-emitting material layer from being affected by the air and moisture, which is conducive to ensuring a display reliability of the display panel. In some other embodiments, the encapsulation layer 60 in the display panel may also adopt another feasible structure, which is not specifically limited herein.

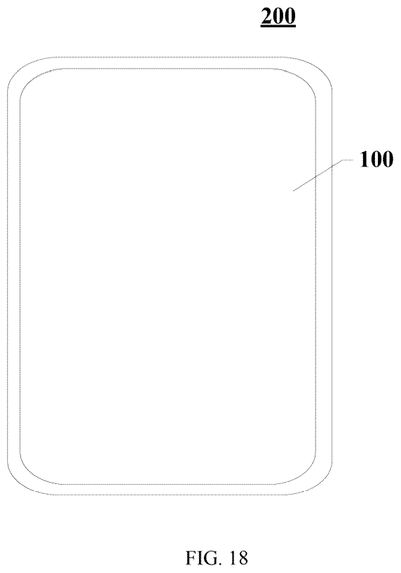

Based on a same inventive concept, the present disclosure also provides a display device. FIG. 18 illustrates a schematic diagram of a display device consistent with various embodiments of the present disclosure. The display device includes the display panel 100 provided by the above embodiments.

It can be understood that the display device 200 provided in one embodiment may be a mobile phone, a tablet, a computer, a TV, a vehicle display device, and other display devices with display functions and touch capabilities, which is not specifically limited herein. The display device provided by the embodiment has beneficial effects of the display panel provided by the embodiments. Details can be referred to in the specific descriptions of the display panel in the above embodiments, which are not limited herein.

As disclosed, the display panel and the display device provided by provided by the present disclosure at least realize the following beneficial effects.

In the display panel and display device provided by the present disclosure, the color filter layer is arranged on a side of the light-emitting layer away from the substrate. The color resists of the color filter layer are arranged corresponding to the pixel openings of the light-emitting layer. Light emitted by sub-pixels corresponding to the pixel opening is emitted through the corresponding color resist, which can filter a spectrum of the sub-pixels. A color purity is higher, which is conducive to improving the display effect. Moreover, the light-shielding layer between adjacent color resists can absorb ambient light to achieve the effect of blocking the reflection of ambient light. The color resists include a first color resist, a reflective layer is arranged between the first side of the first color resist and the light-shielding layer. Part of light emitted from the area of the pixel opening corresponding to the first color resist is emitted to the reflective layer, is further returned to the pixel opening after being reflected by the reflective layer and is emitted to the first color resist from the first color resist to the light emitting surface of the display panel after light passes through the reflection of the inner film layer of the pixel opening. The introduction of the first color resist and the reflective layer effectively utilizes the originally consumed light, which is conducive to improving the light extraction efficiency of a corresponding area of the first color resist and improving the overall light extraction efficiency of the display panel.

Although specific embodiments of the present disclosure have been described in detail by way of examples, a person skilled in the art should understand that the above embodiments are for illustration only, rather than limiting the scope of the present disclosure. A person skilled in the art can make modifications without departing from the scope and spirit of the present disclosure. The scope of the present disclosure is defined by the appended claims.

What is claimed is:

1. A display panel, comprising a substrate, a light-emitting layer on a side of the substrate, and a color filter layer on a side of the light-emitting layer away from the substrate, wherein:
the light-emitting layer includes a plurality of pixel openings, the color filter layer includes a plurality of color resists, a light-shielding layer is filled between adjacent color resists, and along a first direction, the plurality of color resists overlaps the plurality of pixel openings, and the first direction is perpendicular to a plane where the substrate is located;
a color resist of the plurality of color resists includes a first surface and a second surface oppositely arranged along the first direction, and a first side connecting the first surface and the second surface, the light-shielding layer covers the first side, and the first surface is between the second surface and the substrate;
the plurality of color resists includes a first color resist, in the first color resist, along the first direction, an orthographic projection of the first side facing the substrate at least partially overlaps an orthographic projection of the first surface facing the substrate; and
the display panel further includes a reflective layer between the light-shielding layer and the first side of the first color resist.

2. The display panel according to claim 1, wherein in the light-shielding layer, a surface covering the first side of the first color resist has a curved structure.

3. The display panel according to claim 2, wherein:
the light emitting layer includes anodes, light emitting material layers and a cathode, the light emitting material layers are filled in the plurality of pixel openings, the anodes are on sides of the light emitting material layers facing the substrate, and the cathode is on sides of the light-emitting material layers away from the substrate; and
a surface of the light-shielding layer covering the first side has a concave mirror structure and a focus of the concave mirror is on a surface of an anode facing the cathode.

4. The display panel according to claim 1, wherein a surface of the light-shielding layer in contact with the reflective layer is a first slope, and an angle between the first slope and the first surface of the first color resist is an acute angle.

5. The display panel according to claim 1, wherein:
the light-emitting layer includes light-emitting material layers, and the light-emitting material layers include a first color light-emitting material layer, a second color light-emitting material layer, and a third color light-emitting material layer, and a same pixel opening is filled with a light-emitting material layer of a single color;
a light-emitting efficiency of the first color light-emitting material layer is lower than a light-emitting efficiency of the second color light-emitting material layer, and is lower than a light-emitting efficiency of the third color light-emitting material layer;
the color resists further include a second color resist, in the second color resist, along the first direction, an orthographic projection of the first side to the substrate does not overlap an orthographic projection of the first surface to the substrate; and
the first color resist is arranged above a pixel opening corresponding to the first color light emitting material layer, and the second color resist is arranged above a pixel opening corresponding to at least one of the second color light emitting material layer and the third color light emitting material layer.

6. The display panel according to claim 1, wherein:
the light-emitting layer includes light-emitting material layers, and the light-emitting material layers include a first color light-emitting material layer, a second color light-emitting material layer, and a third color light-emitting material layer, and a same pixel opening is filled with a light-emitting material layer of a single color; and
color resists corresponding to pixel openings of the first color light emitting material layer, the second color light emitting material layer and the third color light emitting material layer are the first color resists.

7. The display panel according to claim 1, wherein:
the light-emitting layer include a light-emitting material layers, the light-emitting material layers include a first color light-emitting material layer and a second color light-emitting material layer, a same pixel opening is filled with a light-emitting material layer of a single color, and a light-emitting efficiency of the first color light-emitting material layer is lower than a light-emitting efficiency of the second color light-emitting material layer;
the first color resists are respectively arranged above pixel openings corresponding to the first color light-emitting material layer and above the pixel openings corresponding to the second color light-emitting material layer, the first color resist corresponding to the first color light-emitting material layer is a first sub-color resist and the first color resist corresponding to the second color light-emitting material layer is a second sub-color resist; and
the first side of the first color resist is a plane, an angle between the first side and the first surface of the first sub-color resist is α1, an angle between the first side and the first surface of the second sub-color resist is α2, and α1<α2.

8. The display panel according to claim 1, wherein:
the light-emitting layer includes light-emitting material layers, the light-emitting material layers include a first color light-emitting material layer and a second color light-emitting material layer, a same pixel opening is filled with a light-emitting material layer of a single color, and a light-emitting efficiency of the first color light-emitting material layer is lower than a light-emitting efficiency of the second color light-emitting material layer;
the first color resists are respectively arranged above pixel openings corresponding to the first color light-emitting material layer and above the pixel openings corresponding to the second color light-emitting material layer, the first color resist corresponding to the first color light-emitting material layer is a first sub-color resist and the first color resist corresponding to the second color light-emitting material layer is a second sub-color resist; and
the first side of the first color resist is a curved surface, a radius of the first side of the first sub-color resist is s1, a radius of the first side of the second sub-color resist is s2, and s1<s2.

9. The display panel according to claim 8, wherein an area of a pixel opening corresponding to the first color light-emitting material layer is larger than an area of a pixel opening corresponding to the second color light-emitting material layer.

10. The display panel according to claim 1, wherein:
a display area of the display panel includes a central area and an edge area, and the edge area is arranged at edge positions of the display area around the central area;
for a same light-emitting color, in the edge area, an angle between the first side and the first surface of the first color resist is α01, and in the central region, an angle between the first side and the first surface of the first color resist is α02, and α01>α02.

11. The display panel according to claim 1, wherein in correspondingly arranged color resist and pixel opening, an area of an orthographic projection of the second surface to the substrate is greater than or equal to an area of the pixel opening.

12. The display panel according to claim 1, wherein in the first color resist, an angle between the first side and the first surface is α, 40°≤α≤60°.

13. The display panel according to claim 1, wherein:
the light-emitting layer includes anode, light-emitting material layers and a cathode, the light-emitting material layers are filled in the plurality of pixel openings, the anodes are on sides of the light-emitting material layers facing the substrate, and the cathode is on sides of the light-emitting material layers away from the substrate; and
at least part of light emitted by the light-emitting material layer is directed to the reflective layer, reflected by the reflective layer to a reflection point on the anode, and light reflected by the reflection point is a first reflected light, an angle between the first reflected ray and a normal of a plane where the anode is located is θ, θ≤arccos(H/S), H is a vertical distance between the reflection point and the second surface of the first color resist, and S is a length of a line connecting the reflection point and the edge of the light-shielding layer.

14. The display panel according to claim 2, wherein a distance between the reflection point and a central point of the anode is D, and D>0.

15. The display panel according to claim 1, wherein:
in the first color resist and the pixel opening overlapping along the first direction, an orthographic projection of the pixel opening to the substrate is a first projection, an orthographic projection of the second surface in the first color resist to the substrate is a second projection, and the second projection is on a periphery of the first projection; and
the first projection is a first polygon including a first area and a second area adjacent to the first area, the first area includes corners, the second area includes straight-line edges; a minimum distance between vertexes of the corners in the first area and the second projection is smaller than a minimum distance between the straight-line edges of the second area and the second projection.

16. The display panel according to claim 15, wherein in the second projection, at least edges adjacent to the corners are arc edges.

17. The display panel according to claim 1, further comprising a driving layer and an encapsulation layer, wherein:
along the first direction, the driving layer is between the substrate and the light-emitting layer, and the encapsulation layer is between the light-emitting layer and the color filter layer; and
the driving layer includes a driving transistor, the driving transistor is electrically connected to the light-emitting layer.

18. A display device comprising a display panel comprising a substrate, a light-emitting layer on a side of the substrate, and a color filter layer on a side of the light-emitting layer away from the substrate, wherein:
the light-emitting layer includes a plurality of pixel openings, the color filter layer includes a plurality of color resists, a light-shielding layer is filled between adjacent color resists, and along a first direction, the plurality of color resists overlaps the plurality of pixel openings, and the first direction is perpendicular to a plane where the substrate is located;
a color resist of the plurality of color resists includes a first surface and a second surface oppositely arranged along the first direction, and a first side connecting the first surface and the second surface, the light-shielding layer covers the first side, and the first surface is between the second surface and the substrate;
the plurality of color resists includes a first color resist, in the first color resist, along the first direction, an orthographic projection of the first side facing the substrate overlaps an orthographic projection of the first surface facing the substrate; and
the display panel further includes a reflective layer between the light-shielding layer and the first side of the first color resist.
